(19) United States
(12) Patent Application Publication
(10) Pub. No.: US 2024/0282844 A1
(43) Pub. Date: Aug. 22, 2024

(54) ULTRAVIOLET SPIN BASED SYSTEM AND METHOD

(71) Applicant: KING ABDULLAH UNIVERSITY OF SCIENCE AND TECHNOLOGY, Thuwal (SA)

(72) Inventors: Hadeel ALAMOUDI, Thuwal (SA); Iman S. ROQAN, Thuwal (SA)

(21) Appl. No.: 18/442,767

(22) Filed: Feb. 15, 2024

Related U.S. Application Data
(60) Provisional application No. 63/446,037, filed on Feb. 16, 2023.

(51) Int. Cl. H01L 29/66; H01L 31/032; H01L 31/0352; H01L 31/109; H01L 31/12

(52) U.S. Cl. CPC H01L 29/66984; H01L 31/0321; H01L 31/035218; H01L 31/109; H01L 31/125

(57) ABSTRACT

An ultraviolet based spin-electronics device includes a Si-based substrate, an n-type semiconductor layer located on the Si-based substrate, wherein the n-type semiconductor layer includes an Sn-doped β-Ga₂O₃ material, a p-type semiconductor layer located on the n-type semiconductor layer to form a p-n junction, the p-type semiconductor layer including MnO quantum dots, QDs, and first and second electrodes electrically connected to the n-type semiconductor layer and the p-type semiconductor layer, respectively. Spins of charge carriers in the p-type semiconductor layer are aligned according to a first direction when incident UV light has a first polarization, and according to a second direction, opposite to the first direction, when the incident UV light has a second polarization, different from the first polarization.

### CROSS-REFERENCE TO RELATED APPLICATIONS

This application claims priority to U.S. Provisional Patent Application No. 63/446,037, filed on Feb. 16, 2023, entitled “SOLAR-BLIND/VISIBLE-BLIND DEEP UV SPIN-OPTOELECTRONIC SPIN-PHOTOVOLTAIC FOR FLEXABLE AND LARGE SCALE APPLICATIONS,” the disclosure of which is incorporated herein by reference in its entirety.

### BACKGROUND OF THE INVENTION

### Technical Field

Embodiments of the subject matter disclosed herein generally relate to a system and method for a high-responsivity, solar-blind, self-powered, ultraviolet (UV) optoelectronic device operating under ambient conditions, and more particularly, to spin-based UV optoelectronic devices.

### Discussion of the Background

Conventional electronic devices are based on charged particles (electrons and/or holes) which are collected at their respective terminals. However, in the last decade, the modern technology industry has started to rely on spintronics (the spin associated with a charged particle, for example, the electron) for allowing information to be stored. A quantum number corresponding to the charged particle “spin” (half-integer values for fermions and integers for bosons) is related to the magnetic properties (magnetic dipole moment for the charged particle) of the material rather than the electrical current. These devices are expected to consume much less energy compared to their conventional counterparts.

As a result, the spin-based devices may be adopted in magnetic computer memories, reading heads, mass storage devices, and magnetic random access memory (magnetic RAM) as they can compress enormous amounts of data into a small space. Their range of applications also extends to the medical field, such as magnetic valves and cancer sensors.

A new branch of this field emerged by combing spintronics with optical characteristics, giving rise to spin-optical devices or spin-optoelectronics, such as spin-emitting devices, spin-photodiodes/spin-photodetectors and spin-solar cells/spin-photovoltaic cells. In particular, the conventional photodiodes or photovoltaic devices are based on exciting charge carriers (electrons and/or holes) by incident light (photons), which produces an electrical current which is either measured for determining the amount of incident light, or stored for later use as electrical power. However, such devices solely rely on the incident light intensity, i.e., the energy carried by the photons making up the incident light.

Differently, in spin-photodiodes, spin-photodetectors, and spin-photovoltaic cells (collectively called herein “spin-optoelectronics”), the working concept is based on the spin of the incoming light (i.e., the spin of the photons). Therefore, there is no need for charged particles to be electrically injected because the spin-optoelectronic devices are excited (operated) by exposing them to circularly polarized light, which can spin-polarize the charge carriers. Consequently, the spin of excited carriers (electrons or holes) can be selected to obtain the favored carrier direction depending on the photon spin of the incident polarized light. Thus, it would be feasible to select the preferred carrier (electrons/holes) to deduce the polarization of the light emitted from spin-light emitters (such as lasers).

In this case, the spin angular momentum of the charge carriers (electrons/holes) is used to magnetically control the photo-detection of circularly polarized light in the system, by converting such input signal into a spin-polarized current. Such devices can work under different voltages (spin-photodiodes) or under zero voltage (spin-solar cells or spin-photovoltaic cells). However, in these devices, the spins of the charge carriers must be aligned, as no information can be stored when the generated carriers have a random spin.

In addition, if a p-n junction semiconductor-based device is illuminated by circularly polarized light, a spin-voltaic or spin-optic effect occurs in the magnetic/non-magnetic p-n junction (i.e., either the p-type or the n-type semiconductor is ferromagnetic), leading to spin-split bands. In particular, spin-photodiodes/spin-photodetectors based on semiconductors include several stacked materials/layers: a semiconductor (gallium arsenide, already widely used in electronics) to convert incident photons into charge carriers (electrons/holes), an insulator that regulates the passage of electrons via the tunneling effect, and a ferromagnetic metal that is used to inject electrons that possess a particular spin direction into the semiconductor layer [1].

However, the existing spin-optoelectronic devices operate in the visible-infrared spectral range of the light and are fabricated by complex vacuum processing methods. In addition, none of these devices are flexible. Thus, there is a need for a new device and method that overcomes the above shortcomings.

### SUMMARY OF THE INVENTION

According to an embodiment, there is a spin-electronics transceiver for ultraviolet (UV) communications, and the transceiver includes a Si-based substrate, an n-type semiconductor layer located on the Si-based substrate, wherein the n-type semiconductor layer includes an Sn-doped β-Ga₂O₃ material, a p-type semiconductor layer located on the n-type semiconductor layer to form a p-n junction, the p-type semiconductor layer including MnO quantum dots, QDs, and first and second electrodes electrically connected to the n-type semiconductor layer and the p-type semiconductor layer, respectively. Spins of charge carriers in the p-type semiconductor layer are aligned according to a first direction when incident UV light has a first polarization, and according to a second direction, opposite to the first direction, when the incident UV light has a second polarization, different from the first polarization. The first direction is associated with ones and the second direction is associated with zeros of digital data.

According to another embodiment, there is a spin-optoelectronics storage device that includes a Si-based substrate, an n-type semiconductor layer located on the Si-based substrate, wherein the n-type semiconductor layer includes an Sn-doped β-Ga₂O₃ material, a p-type semiconductor layer located on the n-type semiconductor layer to form a p-n junction, the p-type semiconductor layer including MnO quantum dots, QDs, and first and second electrodes electrically connected to the n-type semiconductor layer and the p-type semiconductor layer, respectively. Spins of charge carriers in the p-type semiconductor layer are aligned according to a first direction when incident light has a first polarization, and according to a second direction, opposite to the first direction, when the incident light has a second polarization, different from the first polarization. The charge carriers are stored in the p-type semiconductor layer, charge carriers with spins aligned along the first direction correspond to ones of digital data, and charge carriers with spins aligned along the second direction correspond to zeros of the digital data.

According to yet another embodiment, there is a solar-blind, visible-blind, photodetector for deep ultraviolet (UV) light that includes a Si-based substrate, an n-type semiconductor layer located on the Si-based substrate, wherein the n-type semiconductor layer includes an Sn-doped β-Ga₂O₃ material, a p-type semiconductor layer located on the n-type semiconductor layer to form a p-n junction, the p-type semiconductor layer including MnO quantum dots, QDs, and first and second electrodes electrically connected to the n-type semiconductor layer and the p-type semiconductor layer, respectively. The p-n junction transforms the UV light into an electrical current.

### BRIEF DESCRIPTION OF THE DRAWINGS

For a more complete understanding of the present invention, reference is now made to the following descriptions taken in conjunction with the accompanying drawings, in which:

FIG. 1 is a schematic diagram of a method for making a self-powered, solar-blind, UV or deep UV (also called UV-C band, i.e., wavelength less than 280 nm) photodetector;

FIG. 2A illustrates I-V curves of a n-β-Ga₂O₃ microflake/p-MnO quantum dots (QDs) junction;

FIG. 2B illustrates the device of FIG. 2A photo-responsivity and detectivity under different bias voltages for a similar illumination power of 244 nm

FIG. 2C illustrates the photoresponse time of the n-β-Ga₂O₃ microflake/p-MnO QD junction when compared to a bare Sn-doped β-Ga₂O₃ device under 244 nm illumination at −5 V;

FIG. 3A illustrates the photo responsivity and detectivity with voltage dependence for n-β-Ga₂O₃ microflake/p-MnO QD heterojunction;

FIG. 3B illustrates the wavelength dependence of the photo-responsivity of the n-β-Ga₂O₃ microflake/p-MnO QD device compared to the bare Sn-doped β-Ga₂O₃ device under −5 V;

FIG. 3C illustrates the I-V curve under low bias of the device of FIG. 1;

FIG. 4 shows a comparison between the device of FIG. 1 characteristics and reported values for self-powered, solar-blind, DUV photodetectors;

FIGS. 5A to 5F illustrate X-ray photoelectron spectroscopy (XPS) measurements and band-alignment of (001)-oriented n-β-Ga₂O₃ microflake/p-MnO QD heterointerface, with FIG. 5A showing the Mn 2p core-level and valence band spectrum for the MnO QDs film, FIG. 5B showing Ga 2p core-level and valence band spectrum for the Ga₂O₃ film, FIG. 5C showing Mn 2p and Ga 2p core-levels for the Ga₂O₃/MnO heterojunction, FIG. 5D showing a schematic representation of the band alignment at the n-β-Ga₂O₃ microflake/p-MnO QDs heterointerface, FIG. 5E showing the work functions of separated p-type MnO QDs and n-type β-Ga₂O₃, and FIG. 5F showing the band-alignment of the device based on the n-type β-Ga₂O₃ microflake/p-type MnO heterojunction after merging them as a device and under illumination;

FIG. 6 illustrates the strong ferromagnetic behavior of a MnO QDs layer that is part of the device of FIG. 1;

FIGS. 7A and 7B illustrate the working principle of a Mn QDs-based spin-optoelectronic device;

FIG. 8A illustrates a Mn QDs-based spin-optoelectronic device having a Schottky or p-n junction structure and FIG. 8B illustrates a Mn QDs-based spin-optoelectronic device having a p-i-n structure;

FIG. 9A illustrates a Mn QDs-based spin-optoelectronic transceiver emitting left-handed, circularly polarized light and FIG. 9B shows the same device emitting right-handed, circularly polarized light; and

FIG. 10 illustrates a structure of a spin-optoelectronic memory device.

### DETAILED DESCRIPTION OF THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to a solar-blind, visible-blind, deep UV spin-optoelectronic device for flexible and large scale applications, for example, a memory device, a transceiver, or a photodetector. However, the embodiments to be discussed next are not limited to these devices, but may be applied to other devices as noted above.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to an embodiment, a novel spin-optoelectronics device (e.g., photodetector or photodiode or transceiver or memory cell) includes a substrate, e.g., SiO₂, an n-type Sn-doped β-Ga₂O₃ microflake (a microflake has a length in the order of mm, e.g., 10 mm, a thickness in the order of 1 μm or less, e.g., 700 nm, and a width in the order of μm, e.g., about 200 μm) located on the substrate, and a p-type layer, including MnO quantum dots (QDs), located on the microflake. This spin-optoelectronics device may be used as a memory element as discussed later. Prior to discussing the various applications of the spin-optoelectronics device, a method for making such a device is introduced and various characteristics of the device are presented. The n- and p-layers form a junction, or heterostructure.

Solar-blind, self-powered, UV-C photodevices (e.g., photodetectors) suffer from low performance, while heterostructure-based devices require complex fabrication and lack p-type wide bandgap semiconductors (WBGSs) operating in the UV-C region (<290 nm). Note that while the Sun emits UV light, the UV-C light is mostly absorbed by the atmosphere and thus, UV-C is considered to not reach a photodetector located on the Earth's surface. According to one or more of the following embodiments, the aforementioned issues are mitigated by introducing a simplified fabrication process for a high-responsivity, solar-blind, self-powered, UV-C device based on a p-n WBGS heterojunction, operating under ambient conditions. Here, both p-type and n-type ultra-wide bandgap WBGSs (≥4.5 eV) are introduced for the first time. In one application, the p-n heterojunction includes a p-type solution-processed manganese oxide quantum dots (MnO QDs) and an n-type Sn-doped β-Ga₂O₃ microflake (one single microflake or plural microflakes). Highly crystalline p-type MnO QDs are synthesized using cost-effective pulsed femtosecond laser ablation in ethanol (FLAL), while the n-type Ga₂O₃ microflakes are prepared by exfoliation. The solution-processed QDs are uniformly drop-casted on the exfoliated Sn-doped β-Ga₂O₃ microflake to fabricate p-n heterojunction device, resulting in excellent solar-blind UV-C photoresponse characteristics (with a cut-off˜265 nm). Further analyses using XPS demonstrate the good band alignment between p-type MnO QDs and β-Ga₂O₃ microflake with type-II heterojunction. Superior photo-responsivity (922 A/W) is obtained under bias, while the self-powered responsivity is ˜83 A/W.

More specifically, a Ti-sapphire femtosecond (fs) laser was used to synthesize the solution-processed MnO QDs in ethanol by FLAL method, and was applied under operative conditions of 150 fs pulse width and 76 MHz pulse repetition rate, at 800 nm wavelength and 1.75 W power. The Sn doped β-Ga₂O₃ microflake was prepared by exfoliation from commercial conductive (100) orientation Sn-doped β-Ga₂O₃ wafer with 5.5×10¹⁸ cm⁻³ donor concentration.

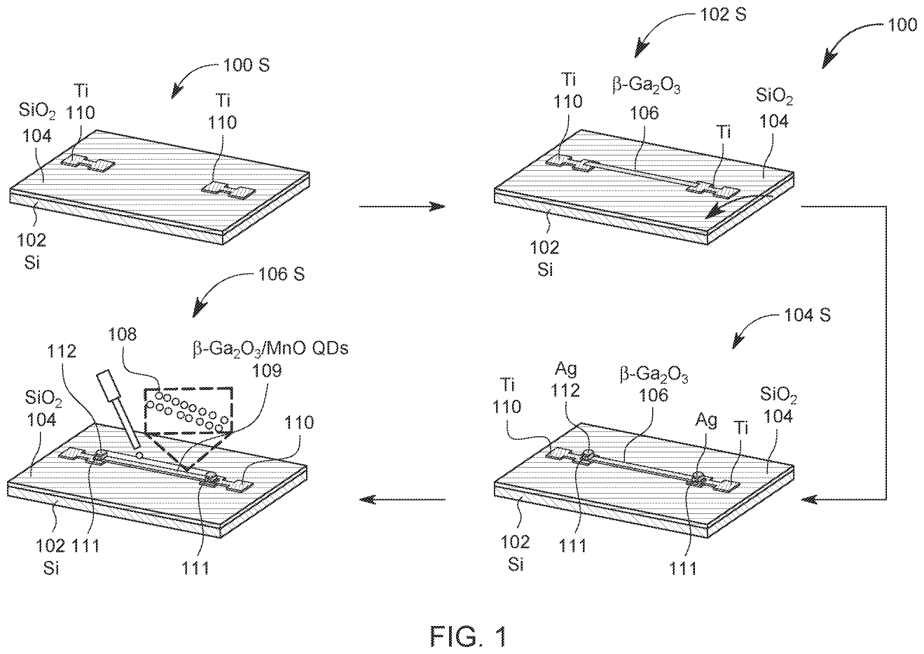

Titanium (Ti) electrodes 110 were deposited, in step S100, on the silicon dioxide substrate (SiO₂) 104 by e-beam evaporation, as shown in FIG. 1. Note that SiO₂ substrate 104 may be a top layer of a Si block 102. A commercial (100)-surface orientation Sn-doped β-Ga₂O₃ wafer (not shown) was used to exfoliate microflakes 106, which were subsequently transferred in step S102 onto the SiO₂ substrate 104 via repeated mechanical exfoliation using a commercial scotch tape. The Sn-doped β-Ga₂O₃ microflakes directly contact the Ti electrodes. Silver (Ag) metal contacts 112 were deposited in step S104, onto a dielectric material 111, located on top of the Ti electrodes, above the ends of the flake 106, after which the microflakes were placed in furnace for few minutes under 150° C. The MnO QDs 108 in ethanol were deposited in step S106, by drop-casting colloidal QD solution on a heated (80° C.) substrate to form the Sn-doped β-Ga₂O₃/MnO QDs junction 109. The junction 109 with the substrate 104 and the contacts 110/112 form a spin-optoelectronics device 100. Note that the MnO QDs 108 are in this embodiment in direct contact with the Sn-doped β-Ga₂O₃ microflakes 106 and with the Ag metal contacts 112. The process discussed above is suitable for large-scale fabrication, even though, in this document, all embodiments are discussed with reference to a single microflake. As the p-type MnO QDs are drop-casted on the n-type Sn-doped β-Ga₂O₃ microflake, a large surface area for the p-n interface 109 is created, resulting in high surface area-to-volume ratio.

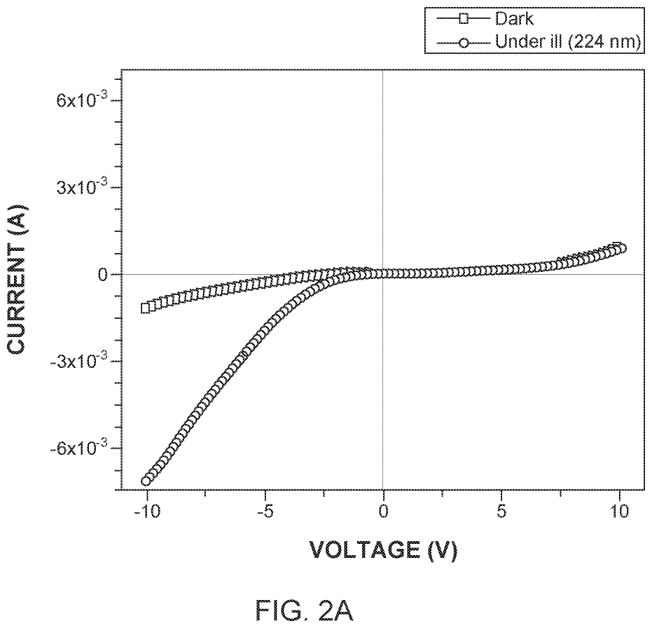

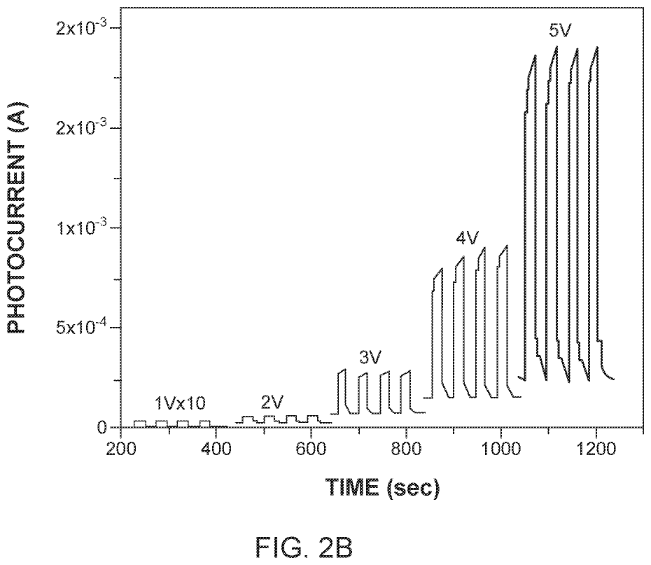

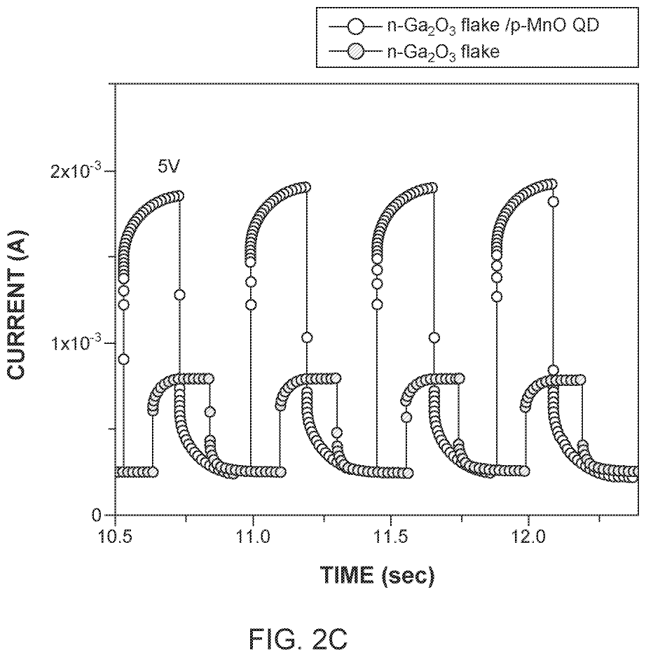

To determine the spin-optoelectronics device 100 response, current-voltage (I-V) measurements were carried out in the dark and under 244 nm illumination as the bias voltage increased from −10 V to 10 V. As illustrated in FIG. 2A, the device exhibits an asymmetric I-V behavior, as it switches on under reverse bias only, which is a typical p-n photodiode behavior. Moreover, under −5 V bias, the dark current is ˜0.3 mA, and it increases by one order of magnitude (>2 mA) under illumination, while under −10 V bias, the photocurrent exceeds 7.5 mA. FIG. 2B further shows that the dark current increases slightly while the photocurrent increases rapidly as the bias voltage increases from −1 to −5 V, showing significant performance enhancement due to the p-n heterojunction structure. The dark current is low at voltages below 4 V and there is no dark current under 0 V, whereas increases significantly above 5 V. In p-n devices, the dark current increases as the voltage increases due to the thermal excitation of defect levels such as surface states and dangling bonds in QDs and the microflake.

Therefore, the device 100 can work at low as well as high voltages, as confirmed by the time-transient on/off cycles illustrated in FIG. 2B. FIG. 2C illustrates a comparison between the transient photoresponse of the n-β-Ga₂O₃ microflake/p-MnO QD heterojunction-based device 100 compared to that of a bare Sn-doped β-Ga₂O₃ microflake homojunction-based device under −5 V bias. The photocurrent in the heterojunction-based device 100 is greater by two-fold than that obtained for the homojunction-based device. Thus, the p-n junction 109 enhances the photocurrent while reducing the dark current. These findings are attributed to the beneficial effects of the p-n junction for internal electric field generation, which significantly improves the spatial separation of photo-generated charge carriers. Note that inferior results were obtained with undoped β-Ga₂O₃ microflakes as it is known that undoped β-Ga₂O₃ creates a barrier with metal contacts, preventing carrier transportation. In addition, as the device is based on a p-n junction, in undoped β-Ga₂O₃, the number of donors is insufficient to provide photogenerated electron carriers.

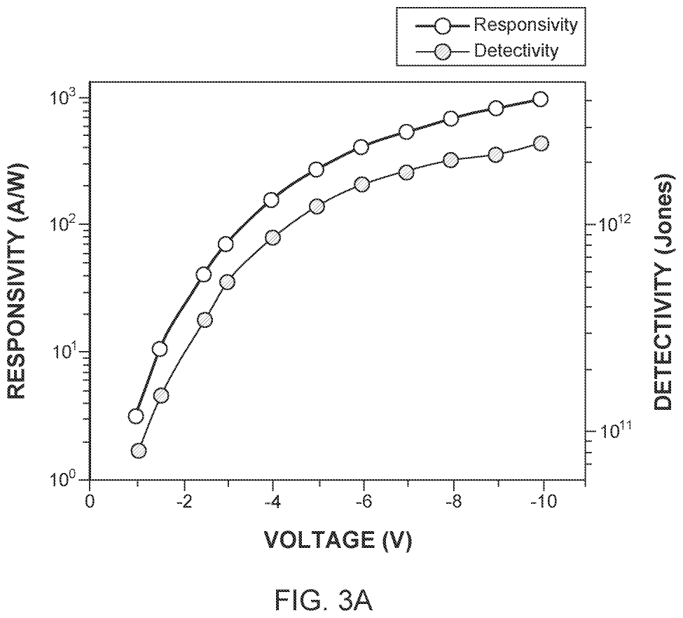

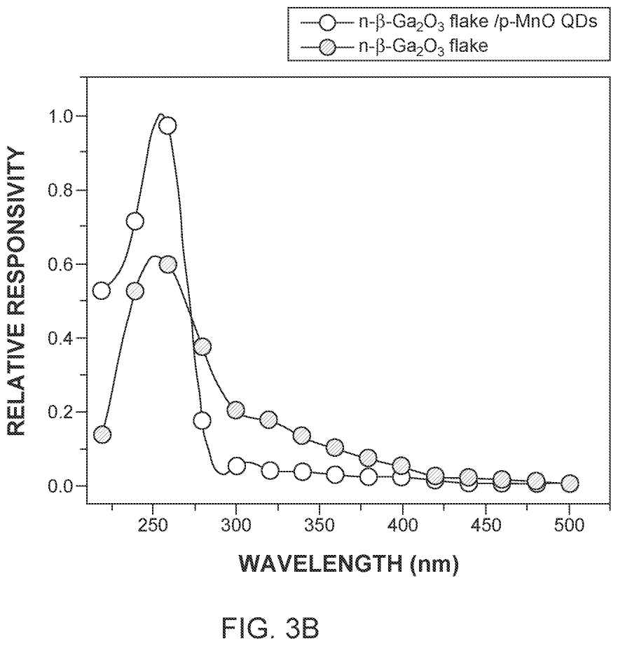

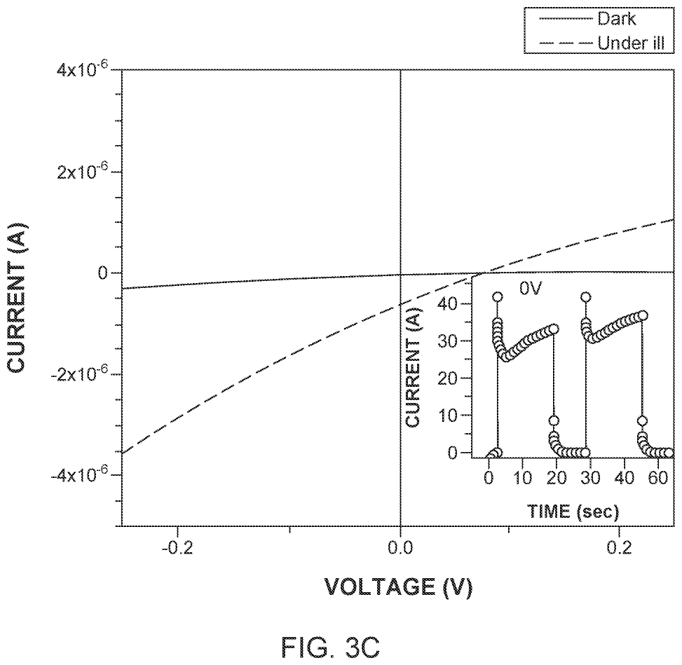

As photo-responsivity (R) and detectivity (D*) are important figure-of-merit parameters that define optoelectronic devices's performance, they were calculated for the n-β-Ga₂O₃ microflake/p-MnO QDs heterojunction-based device 100. As shown in FIG. 3A, under 244 nm DUV illumination at 5 V, R is equal to ˜261.6 A/W, which is about 32% higher than the value obtained for bare Sn-doped β-Ga₂O₃ microflake (83 A/W) under the same conditions. When the bias voltage increased to 10 V, the photo-responsivity of n-β-Ga₂O₃ microflake/p-MnO QDs increased to 922 A/W, corresponding to D*=2.94×10¹³ Jones, as also shown in the figure.

To elucidate the solar-blind characteristics of the n-β-Ga₂O₃ microflake/p-MnO QD heterojunction-based device 100, the wavelength-dependent R was examined under 5 V bias. As shown in FIG. 3B, when compared to that obtained at 300 nm (the UV-B region), much higher photo-responsivity in the UV-C range was achieved, starting from 220 nm, with a sharp cut-off at 265 nm. A high rejection ratio (R₂₆₀/R₃₀₀˜10²) between the photo-responsivity at 260 nm and 300 nm was found, demonstrating superior solar-blind characteristics of n-β-Ga₂₀₃ microflake/p-MnO QD-based device 100, which is due to the large MnO QD bandgap, allowing UV-C detection. These findings are expected, given that, in the p-n junction structure 109, the excitation energy must exceed the bandgap energy of both layers. Specifically, it must be greater than ˜4.9 eV (˜253 nm), where R value is maximum, followed by sharp cut-off at 265 nm, as shown in FIG. 3B, indicating selective photodetection in the UV-C spectral region. On the other hand, the bare Sn-doped β-Ga₂O₃ homojunction-based photodetector exhibits a weaker photoresponse in UV-C, while there is a considerable photoresponse in UV-B and UV-C regions, as also shown in the figure.

In the n-β-Ga₂O₃ microflake/p-MnO QD heterojunction-based device 100, some of the photogenerated carriers can be trapped by the MnO QD surface states before reaching the electrodes (the absorption tail shown in the MnO QDs). This process reduces the UV-B and UV-A photoresponse generated from the β-Ga₂O₃ microflake with a strong cut-off at 265 nm (i.e., 4.9 eV, which is close to the bandgap value of p-MnO QDs), unlike the photodetector based on bare Sn-doped β-Ga₂O₃ microflake that shows UV-B and UV-A photoresponse.

FIG. 3C shows the I-V curve obtained under low bias, while the inset shows the on/off cycle under 0 V bias, demonstrating the self-powered characteristics of the device 100. On the other hand, no response under 0 V bias was observed for the bare Sn-doped β-Ga₂O₃ homojunction-based device. These results are attributed to the fact that, when the n-β-Ga₂O₃ microflake/p-MnO QD-based device 100 is illuminated under reverse bias, the built-in electric field in the depletion region increases, resulting in self-powered or photovoltaic characteristics. In this case, a photo-responsivity of about 83 mA/W was obtained, which is much larger than that measured for the bare MnO QD-based device. Therefore, the p-n junction structure 109 is responsible for the self-powered photoresponse as the built-in electric field facilitates carrier transport before recombination.

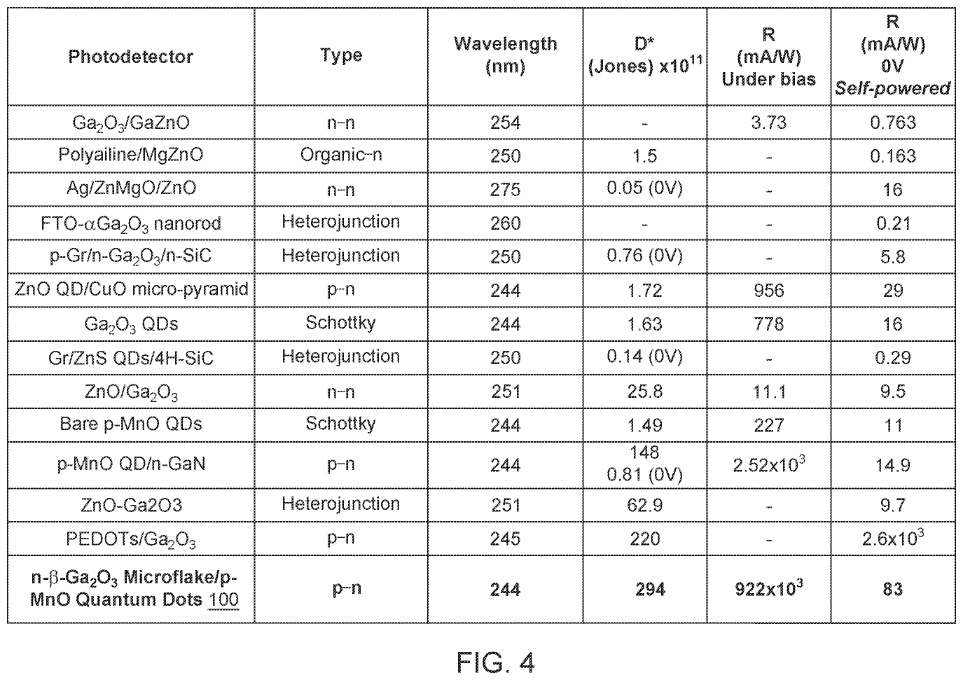

These findings show that the solution-processed UV-C photodevice 100 operating in the A/W range exhibits superior photo-responsivity and detectivity compared to the previously reported solar-blind, self-powered, UV-C photodetectors based on solution-processed QDs (with responsivity in the mA/W range), as shown in the table of FIG. 4. The photo-responsivity of n-β-Ga₂O₃ microflake/p-MnO QD heterojunction-based device 100 is three orders of magnitude higher than that obtained from Schottky UV-C photodetector based on bare solution-processed MnO QDs and other solution-processed QD-based devices. Moreover, it is two orders of magnitude greater than that measured for n-GaN/p-MnO UV-C photodetectors as the GaN bandgap (3.5 eV) is much lower than the β-Ga₂O₃ bandgap. Therefore, the solar-blind, solution-processed QD-based p-n junction-based device 100 operating in the UV-C range has been developed with all active layers characterized by bandgaps exceeding 4 eV and the table in FIG. 4 shows that device 100's responsivity is superior compared to those reported in literature.

To understand the operational mechanism behind the high performance of the device 100, the inventors studied the nature of the heterointerface formed between n-type Sn-doped Ga₂O₃ 106 and p-type MnO 108 by using XPS measurements. High-resolution XPS measurements were conducted to determine the valence band offset (VBO) at the (001)-oriented n-β-Ga₂₀₃ microflake/p-MnO QD heterointerface 109. For this purpose, the energy difference between the Ga 2p_{3/2} and Mn 2p_{3/2} core levels from the n-β-Ga₂O₃ microflake/p-MnO QD heterojunction 109 and the energy of Ga 2p_{3/2} and Mn 2p_{3/2} core levels relative to the respective valence band maxima (VBM) of the Sn-doped β-Ga₂O₃ and p-MnO QDs samples were acquired. The VBO for n-β-Ga₂O₃/p-MnO QD heterojunction can be calculated using the Kraut method for estimating valence (ΔE_{V}) and conduction (ΔE_{C}) band offsets, based on equations (1) and (2):

$$Δ {E}_{V} = ( {E}_{Mn 2 {p}_{3 / 2}}^{MnO - QDs} - {E}_{VBM}^{MnO - QDs} ) - ( {E}_{Ga 2 {p}_{\frac{3}{2}}}^{{Ga}_{2} {O}_{3}} - {E}_{VBM}^{{Ga}_{2} {O}_{3}} ) + ( {E}_{Ga 2 {p}_{\frac{3}{2}}}^{\frac{{Ga}_{2} {O}_{3}}{MnO} - QDs} - {E}_{Mn 2 {p}_{\frac{3}{2}}}^{\frac{{Ga}_{2} {O}_{3}}{MnO} - QDs} ) , \qquad ( 1 )$$

$$Δ {E}_{C} = ( {E}_{g}^{Mn film} - {E}_{g}^{{Ga}_{2} {O}_{3}} ) + Δ {E}_{V} . \qquad ( 2 )$$

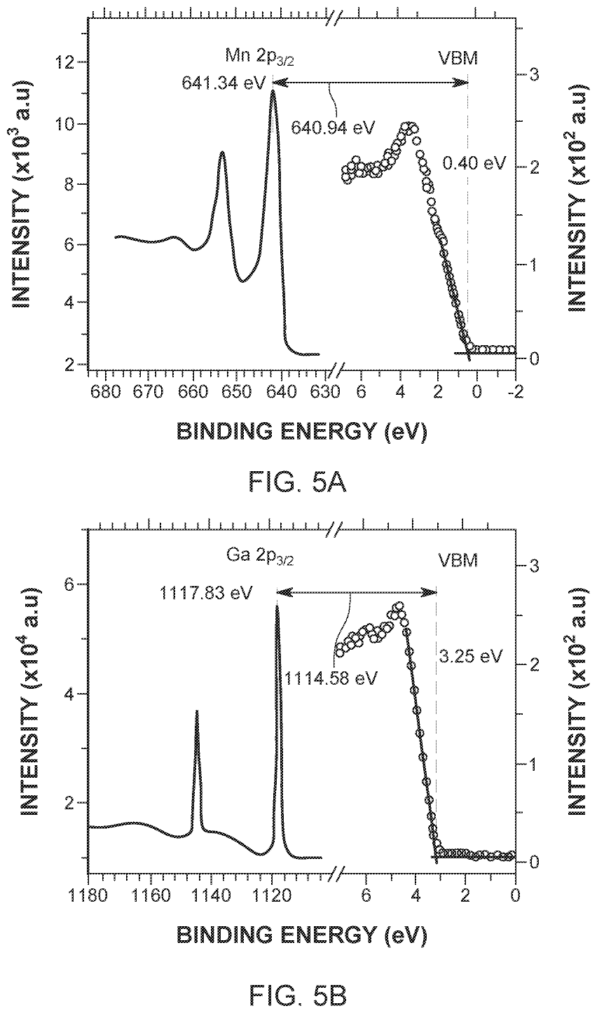

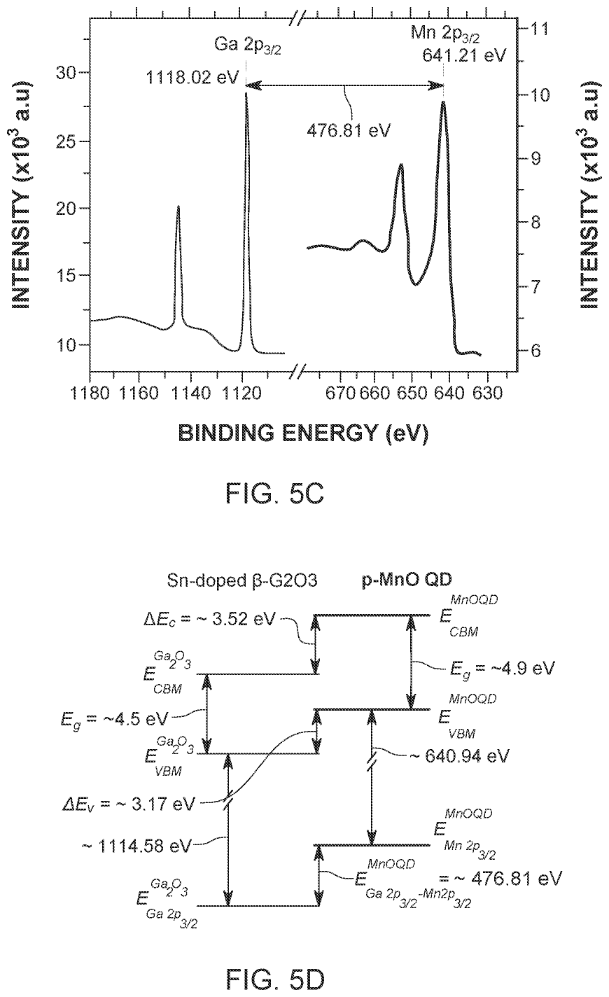

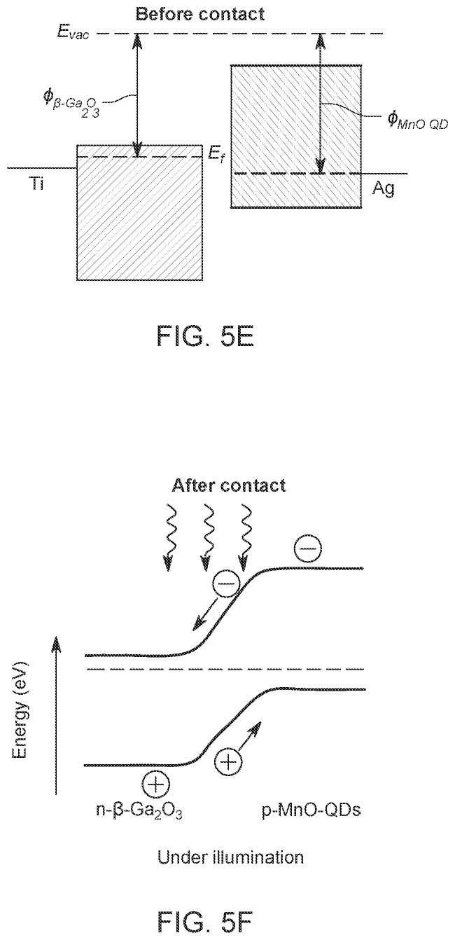

In the Kraut method, the choice of energy calibration (adventitious carbon) does not affect the band alignment to obtain the values of band offset (ΔE_{V} and ΔE_{C}). FIG. 5A shows the Mn 2p core-level and valence band spectra of a bulk Mn sample, indicating that the binding energy of Mn 2p_{3/2} is equal to 641.34 eV, while the VBM is estimated to be 0.40 eV. The separation between the core-level energy of Mn 2p_{3/2} and the VBM, denoted by ΔE_{Mn 2p3/2-VBM}^{MnO-QDs}=(E_{Mn 2p3/2}^{MnO-QDs}−E_{VBM}^{MnO-QDs}) is estimated to be 640.94 eV for the MnO QD sample

FIG. 5B shows the Ga 2p core-level and valence band spectra of the (001)-oriented Sn-doped β-Ga₂O₃ sample. The binding energy of Ga 2p_{3/2} is found to be 1117.83 eV, while the VBM is equal to 3.25 eV. The separation between the core-level energy of Ga 2p_{3/2} and the VBM, calculated using the ΔE_{Ga 2p3/2-VBM}^{Ga}^{₂}^{O}^{₃}=(E_{Ga 2p3/2}^{Ga}^{₂}^{O}^{₃}−E_{VBM}^{Ga}^{₂}^{O}^{₃}) expression, for (001)-oriented Sn-doped β-Ga₂O₃ is determined to be 1114.58 eV.

FIG. 5C shows the Mn 2p and Ga 2p core-level spectra of MnO QD thin film grown on the (001)-oriented Sn-doped β-Ga₂O₃ sample, indicating that the binding energies of Mn 2p_{3/2} and Ga 2p_{3/2} are equal to 641.21 eV and 1118.02 eV, respectively. The energy difference between Ga 2p_{3/2} and Mn 2p_{3/2} core-levels is observed to be 476.81 eV. This value was estimated based on:

$$Δ {E}_{Ga 2 {p}_{3 / 2} - Mn 2 p 3 / 2}^{{Ga}_{2} {O}_{3} / MnO - QDs} = ( {E}_{Ga 2 {p}_{3 / 2}}^{{Ga}_{2} {O}_{3} / MnO - QDs} - {E}_{Mn 2 {p}_{3 / 2}}^{{Ga}_{2} {O}_{3} / MnO - QDs} ) . \qquad ( 3 )$$

After substitution to eq. (1), the VBO value is equal to ΔE_{V}=3.17 eV. Substitution of VBO (ΔE_{V}) obtained from the XPS analysis and the electronic bandgap (E_{g}) values of MnO QDs and (001)-oriented Sn-doped β-Ga₂O₃ samples in eq. (2) allows to determine the conduction band offset (CBO) ΔE_{C} for the (001)-oriented n-β-Ga₂O₃/p-MnO QD heterojunction, which is equal to 3.52 eV. Note that the bandgap values used in this equation were obtained from the absorption measurements (FIG. 3A), which are estimated to be E_{g}^{MnO-QDs}=4.90 eV and ΔE_{g}^{Ga}^{₂}^{O}^{₃}=4.55 eV. The offset parameters of these materials are represented in the schematic diagram shown in FIG. 5D, which demonstrates that the band alignment of the n-β-Ga₂O₃ microflake/p-MnO QD heterojunction is of type II.

The energy diagrams obtained for both β-Ga₂O₃ and MnO QDs are shown in FIG. 5E. Note that this figure shows the Ti electrode 110 contacting the n-type β-Ga₂O₃ layer 106 and the Ag electrode 112 contacting the MnO QDs layer 108. Recently, the inventors estimated the work function (4.87±0.02 eV) and the Fermi level of such p-type MnO QDs using Kelvin probe measurements, whereas the work function of n-type β-Ga₂O₃ was found to be 4.11±0.05 eV. Thus, when the two materials are attached to each other, after drop-casting the QDs on Sn-doped β-Ga₂O₃ (see FIG. 5F), their respective Fermi energies are aligned, forming a p-n type-II heterojunction, which is in line with the XPS measurements. These findings confirm that the significant enhancement in the performance of the device 100 is attributed to the type-II band alignment of the p-n heterojunction formed by n-type (001)-oriented Sn-doped β-Ga₂O₃ microflake and p-type MnO QDs, as well as the ultra-high bandgap (≥4.5 eV) of both layers.

To generate electron-hole pairs under illumination, the photo-generated carriers are created at the p-n junction 109 formed by the n-β-Ga₂O₃ microflake/p-MnO QDs layers, thereby increasing the photocurrent. Due to the excellent band alignment of the n-β-Ga₂O₃ microflake/p-MnO QDs layers in the device 100, as shown in FIG. 5F, the majority of the photogenerated carriers are introduced by route (I) via p-n junction, with a minor contribution from route (II) via Sn-doped β-Ga₂O₃ microflakes only (smaller bandgap).

The band alignment between p-MnO QDs 108 and n-type Sn-doped-β-Ga₂O₃ microflake 106 was confirmed by XPS, which revealed that p-type MnO QD junction 109 with n-type β-Ga₂O₃ microflake boosts the UV-C photocurrent compared to bare n-type β-Ga₂O₃ that relies solely on route (II). This is expected, as route (I) enables the migration of holes from the valence band (VB) of Sn-doped β-Ga₂O₃ microflake to the VB of MnO QDs while allowing the migration of electrons from the conduction band (CB) of the (p-type) p-MnO QDs into the CB of the (n-type) Sn-doped β-Ga₂O₃ microflake.

Additionally, as in this structure, the photon energy needs to be greater than both E_{g[Sn-doped β-Ga2O3 microflake]}=4.55 eV and E_{g[MnO QDs]}=4.9 eV, to satisfy this requirement, 244 nm (5.08 eV) UV-C illumination was used. However, the carrier density produced using route (II) decreases as carrier separation occurs at the MnO QD surface due to the light absorption at the device surface. The favorable formation of the depletion layer in the p-n junction under reverse bias assists in the separation of electron-hole pairs, while the presence of UV-C light suppresses electron-hole recombination. This in turn promotes photocurrent enhancement within the n-β-Ga₂O₃ microflake/p-MnO QD heterojunction 109, resulting in a superior photoresponse compared to the device based on a bare Sn-doped β-Ga₂O₃ microflake homojunction. In addition, such good band alignment between the constituent layers enhances the photovoltaic self-powered characteristics of this heterojunction device, demonstrating that it can be used in applications requiring low energy consumption.

To define the changes in the photoresponse time during rise and decay of the transient signal, the inventors fitted a double-exponential function to the experimental data, as a rapid rise in the photoresponse was followed by a slow rise, while a rapid decay was followed by a slow decay. It was found that the photocurrent rise times τᵣ₁ and τᵣ₂ are estimated at 0.167±0.008 s and 1.18±0.2 s, whereas the decay times τ_{d1} and τ_{d2} are estimated at 0.132±0.01 s and 1.48±0.09 s, respectively. Such slow photoresponse is characteristic of photodetectors based on solution-processed QDs, as the QD surface states act as carrier traps, and thus extend the transient carrier time as such effect inhibits photocarrier mobility. These photoresponse characteristics are comparable to the values reported for other high-performance photodetectors based on β-Ga₂O₃. At the p-n junction, the photoresponse time under reverse bias is reduced due to the increased depletion width, which decreases the junction capacity and increases the drift velocity of charge carriers in the photodetector.

The superior band alignment and band effect in these n-β-Ga₂O₃ microflake/p-MnO QDs devices 100 allow high self-powered, solar-blind performance, which can pave the way for the use of such heterojunction structures in solar-blind photovoltaic devices aimed at space communication, visible-blind fire sensors, and solar-blind receivers in terrestrial communication, as well as in visible blind DUV photodiodes for industrial and research applications, as the currently available commercial UV photodiodes and photodetectors, are mostly based on silicon that is not visible-blind. The term visible-blind means that when the spin-UV or deep UV light is received by the photodetector or memory device, the other spectral range (even if they are polarized) does not interfere with the signal.

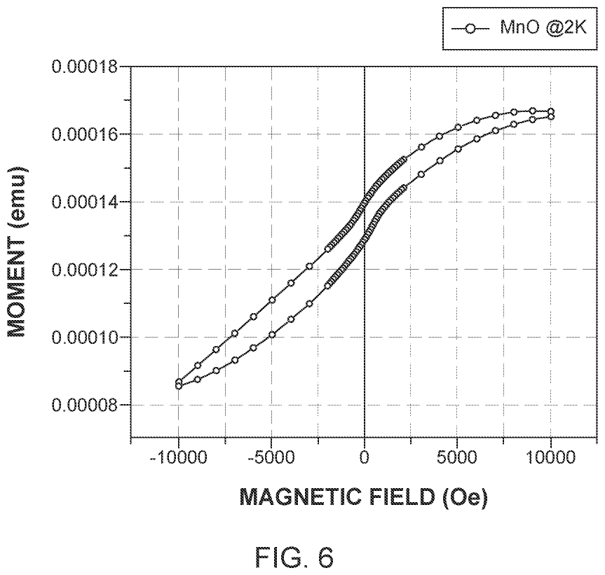

While device 100 may be used as a photodetector, the inventors discovered that the same device exhibits ferromagnetic characteristics, which makes this device suitable for additional applications, for example, spin-optoelectronics devices. The inventors found the ferromagnetism of MnO QDs 108 using SQUID measurements, which resulted in the hysteresis shown in FIG. 6. This hysteresis is the tell-tale sign of ferromagnetic behavior. This result confirms that DUV devices 100 based on the MnO QDs 108 are spin-devices and can be used in isolation (based on Schottky junction) or in combination with other materials such as Ga₂O₃ flakes (based on p-n junction or heterojunction). Moreover, they are suitable for large-scale, cost-effective production of flexible devices (based on lateral or vertical design).

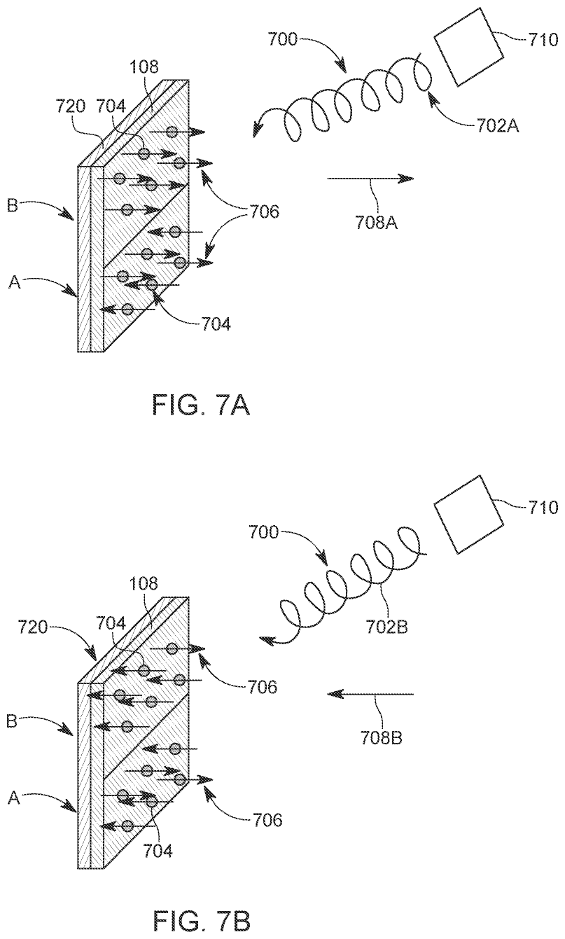

The configuration and operation of a spin-optoelectronic device is now discussed with regard to FIGS. 7A-9B. Initially, the spin-optoelectronic device is considered to act as a receiver or spin-receiver or spin solar cell. The MnO QDs-based optoelectronic and photovoltaic device 100, which is used in this embodiment as a spin-optoelectronic device, works based on the spin of the charge carrier as the MnO layer 108 is a ferromagnetic semiconductor material. In this case, if the MnO QDs layer 108 is used as an active layer or transport layer, the principle of the operation of the device does not depend on the charge carrier or the intensity of the incoming light, in contrast to conventional optoelectronic and solar cell devices. In this case, the MnO QDs based spin-device 100 works based on the spin of the incoming light particles (photons) 700. Therefore, there is no need for the charged particles to be electrically injected into the device as the spin-optoelectronic device is excited (operated) by exposing it to the circularly polarized deep UV light 702A/702B, which can spin-polarize the charge carriers.

FIG. 7A shows only the MnO QDs layer 108 for illustrating the effect of the polarized light 702A onto the charge carriers 704 present in the MnO QDs layer 108. Note that the bottom part A of FIG. 7A shows the spins 706 of the carriers 704 before light illumination. The spins 706 of the charge carriers 704 are randomly distributed in this case. However, after illumination with the polarized light 702A, the charge carriers 704 align their spins 706 to have the same direction 708A, as shown in the top part B of FIG. 7A. Note that the incident light 702A is left-handed, circularly polarized light, and this light acts as a spin injection light. Also, this injection light is a UV or UV-C light and direction 708A is considered a spin-up direction. FIG. 7B shows the charge carriers 704 excited by a right-handed, circularly polarized light 702B, which results in the spins 706 being aligned along a spin-down direction 708B, which is opposite to 708A. FIGS. 7A and 7B also show a source 710 of the polarized light 702A/702B, for example, a laser device.

Consequently, the spin of the excited carriers (electrons or holes) 704 can be selected to obtain a favored (predominant) carrier direction (708A or 708B), depending on the incoming photon 700 spin of the incident polarized deep UV light 702A/702B. Thus, it is possible to select the spin of the preferred carrier (electrons/holes) 704 to determine the polarization of the light emitted from the spin-light emitters (such as lasers) 710, as shown in FIGS. 7A and 7B. In this case, the spin angular momentum 706 of the charge carriers (electrons/holes) 704 is used to magnetically control the photo-detection of circularly polarized light 702A/702B in the system, and to convert such input signal into a spin-polarized current. Such device can work under different voltages (spin-photodiodes) or under zero voltage (spin-solar cells or spin-photovoltaic cells). However, in this device, the spins of the charge carriers 704 need to be aligned, as no information can be stored in generated carriers with random spin.

The spin 706 direction 708A or 708B of the charge carriers 704 depends on the spin of the circularly polarized light 702A/702B. For the case illustrated in FIG. 7A, the left-handed (right-handed) circularly polarized DUV and UV light 702A preferentially excites spin-up (spin-down) 706 electrons 704 in different layers of MnO QDs 108. Thus, the layer 108 (as part of the device 100) exhibits the capability of switching the spin 706 of the carriers 704 depending on the incident polarized light 702A/702B direction, which means that the device 100 may control and manipulate different spin populations within the MnO QDs layer 108, which is a requirement for a spin-optoelectronics device, as discussed in [2]. Device 100 may need another layer to block the opposite spin direction (undesired) and to control the carriers' direction, for example, a chiral-induced spin filter 720.

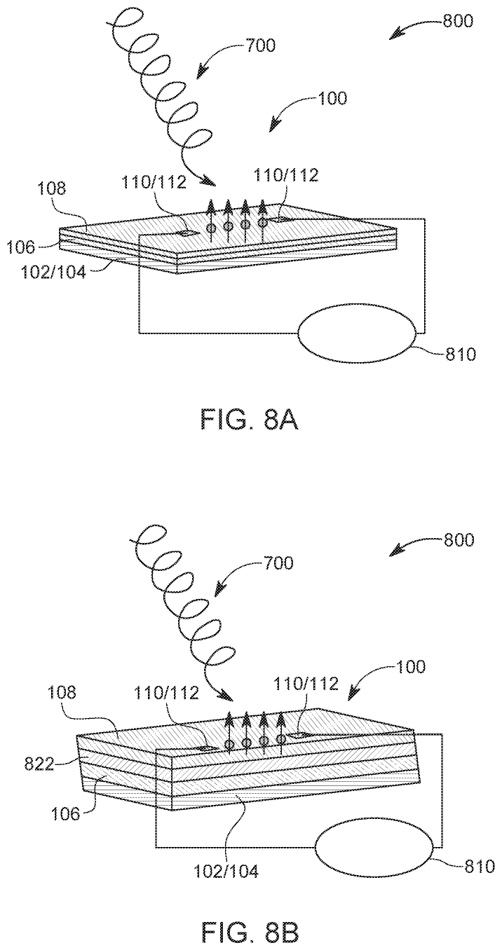

The MnO QDs layer 108 can act as an active layer in a spin-optoelectronics device 800, as shown in FIG. 8A, in a Schottky junction or p-n junction. Alternatively, layer 108 can act as a p-type layer (transport layer) that injects the spin into an active layer 822 in a p-i-n junction device 800, as shown in FIG. 8B. Note that device 800 in FIG. 8B includes an active layer 822 when compared to the device shown in FIG. 8A. The active layer 822 can be an inorganic semiconductor, e.g., GaN, AlGaN or InGaN, III-nitrides, ZnO, perovskite, etc. or an inorganic material, such as perovskite. Both figures show the substrate 102/104 discussed in FIG. 1.

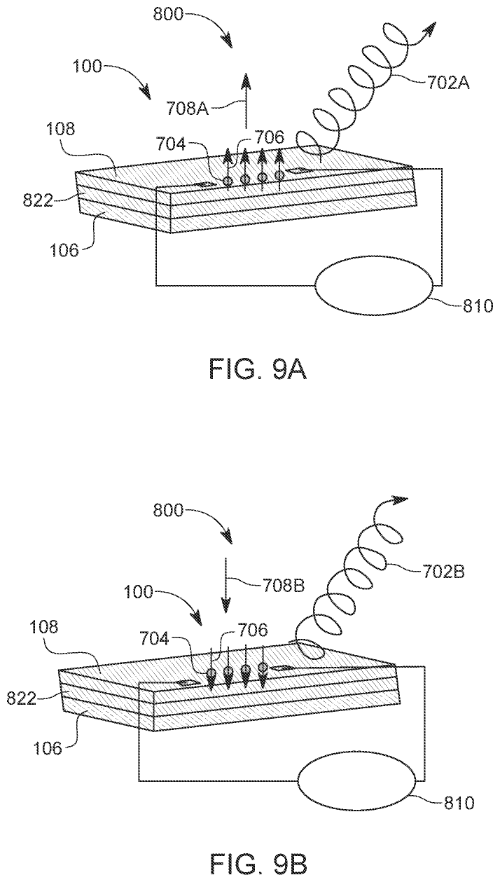

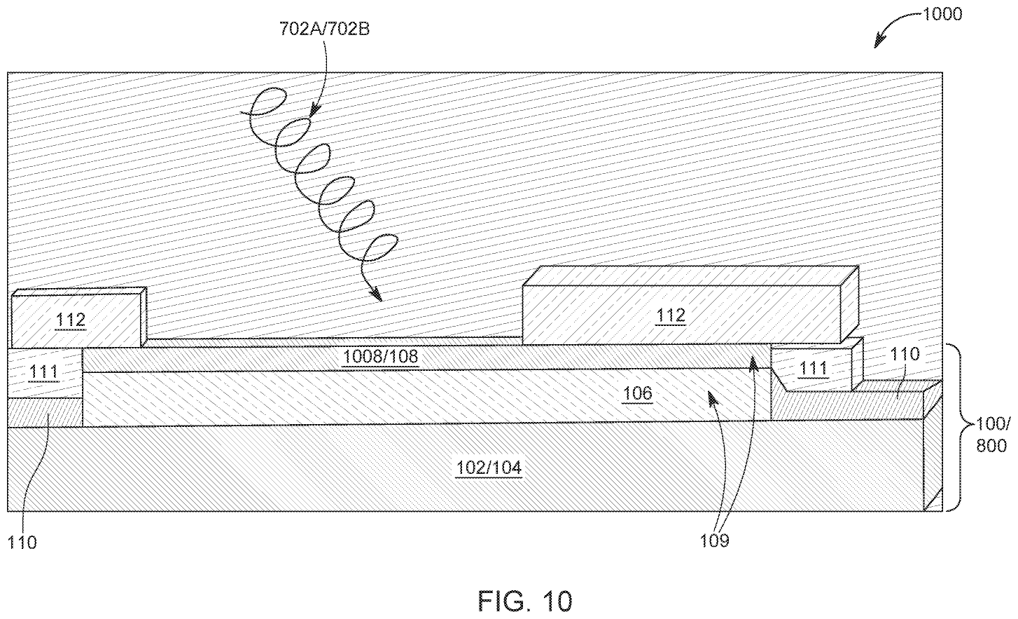

Device 100 may also be used to emit polarized light (i.e., to work as a transmitter) as now discussed with regard to FIGS. 9A and 9B. The MnO QDs layer 108 can act as p-type layer that is able to inject the spin 706 into the active layer 822 to emit spin-polarized light 702A in a spin-emitting device 800, such as a spin-LED or spin-laser diode (spin-LD). The device 800 is shown in FIG. 9A emitting a left-handed circularly polarized light 702A, as the spins 706 are oriented along direction 708A, while the same device emits a right-handed, circularly polarized light 702B, as shown in FIG. 9B, as the spins 706 are oriented along the opposite direction 708B. Thus, the same device 800 may read the incoming polarized light and transform it into a polarized electrical current, that can be decoded at an outer circuit 810 (including electronics and/or power source, which are used in a traditional transceiver) to read an encoded message, as shown in FIGS. 8A and 8B.

Alternatively, or, in addition, as shown in FIGS. 9A and 9B, the same device 800 may be configured to encode information from an outer circuit 810, into the spins 706 of the carriers 704, and to generate polarized light, either right- or left-handed (702A or 702B) so that the encoded information may be transmitted (wireless or in a wired mode) to another similar device.

In one variation of these devices, it is possible to add a spin-filter (720 shown in FIG. 7A) to control which spin is allowed to move through the outer circuit 810 and which is blocked. For example, in one embodiment, the spin-electronics device 800 may contain two layers, one (e.g., layer 108) configured to emit light mainly with a same spin polarization (corresponding to a majority of the carries having a same spin orientation, either up or down) and the other layer (layer 720) to filter or block the minority carriers that have the opposite spin, which is called a chiral-induced spin filter layer. Such a layer is configured to block carriers having their spin opposite to the majority of the carriers. In this case, when the carriers with the correct spin direction pass through the light-emitting layer, they cause the layer to produce photons that move in unison along a spiral path, as schematically illustrated in FIGS. 9A and 9B, and as also discussed in [3], rather than a conventional wave pattern, to produce circular polarized electroluminescence.

In a different embodiment, instead of using the spin filter layer 720, it is possible to apply a minor magnetic field to the device to control the spin of the carriers (either spin up or spin-down). For this case, there is no need for a filter, but it may be necessary to add a polarizer to filter the polarization of the light to be right-handed or left-handed.

It is noted that the conventional optoelectronic devices only control the charge and light intensity, but not the spin of the electrons. The carriers' spin (for electrons and holes) may be viewed, for the devices 100 and 800, as the orientation of the poles and can be assigned a binary information, e.g., an “up” spin is a “1,” and a “down” spin is a “0.” Thus, any digital information that is communicated with “0” and “1” through a traditional radio frequency (RF) transceiver can be communicated with spin up or down. In contrast, conventional electronics only transmit information through bursts of electrons along a conductive wire to convey messages in “1s” and “0s.” Spintronic and spin-optoelectronic devices 100 and/or 800, however, could utilize both methods or only one of them, promising to process exponentially more information than traditional electronics, as also discussed in [3].

The spin-optoelectronics device 100 has been discussed above as being capable of working as a transceiver that transmits information based on the spin up or spin down orientation of its charge carriers, in addition to the traditional RF transmission. The same device can be used, as discussed now with regard to FIG. 10, as a spin-optoelectronics memory device. The figure shows an optoelectronic memory device 1000 that includes a photosensitive layer 1008, which may be the MnO layer 108 discussed above. The device 1000 further includes layer 106 (for example, Sn-doped Ga₂O₃ flakes) for forming the p-n junction 109. Electrodes 112 are connected to the photosensitive layer 1008 and electrodes 110 are connected to the layer 106. Electrodes 112 are separated from electrodes 110 by the dielectric material 111 in this embodiment, similar to the embodiment illustrated in FIG. 1. The Ga₂O₃ microflakes 106 have a potential for optical storage under UV illumination, as noted in [4]. In this embodiment, the MnO QD layer 108 is also used as a photosensitive layer, i.e., a spin injection layer, which results in the spin-optoelectronic memory device 1000, which uses polarized light 702A/702B to receive and store the data. Unlike traditional random memory devices, device 1000 uses the spin of electrons for data storage and transfer.

Thus, the versatility of the device 100 (820, 1000) makes it suitable for being a smart, self-powered DUV device, which is based on wide bandgap semiconductors. This device may have several applications, including biological sensors, military transceivers, sterilization equipment, space communication, etc. The device can work as a receiver such as spin-photodetector, spin-photodiode, spin-solar cell, or emitter or transmitter such as spin-emitter, spin-LED. Additionally, spin-optoelectronic device 100 has the potential for telecommunications, information processing, or medicine. Multiple-state logic and novel communication protocols can be implemented based on the capability of manipulating and detecting the different polarization states of light pulses in integrated platforms without the use of external optical elements. In this framework, novel devices such as optical interconnects, optical switches, and modulators can be realized with reconfigurable functionality depending on the configuration of the magnetic electrodes embedded in the emitters and detectors of the polarized light. The information, ultimately carried out by the spin of the electrons and photons, can be encoded in the confined spin state, manipulated at the nanoscale and redelivered in the form of polarized photons. Possible future applications of such a novel approach includes the areas of quantum computing and data-transmission cryptography based on the coherent interaction between qubits via photon-polarization effects.

The solar-blind, self-powered, DUV device 100 having spintronic characteristics will lead to smart devices that do not interact with visible/solar polarized light and can be used for data transfer in space communication or telecommunication or in medical and biological or industrial applications.

The term “about” is used in this application to mean a variation of up to 20% of the parameter characterized by this term. It will be understood that, although the terms first, second, etc. may be used herein to describe various elements, these elements should not be limited by these terms. These terms are only used to distinguish one element from another. For example, a first object or step could be termed a second object or step, and, similarly, a second object or step could be termed a first object or step, without departing from the scope of the present disclosure. The first object or step, and the second object or step, are both, objects or steps, respectively, but they are not to be considered the same object or step.

The terminology used in the description herein is for the purpose of describing particular embodiments and is not intended to be limiting. As used in this description and the appended claims, the singular forms “a,” “an” and “the” are intended to include the plural forms as well, unless the context clearly indicates otherwise. It will also be understood that the term “and/or” as used herein refers to and encompasses any possible combinations of one or more of the associated listed items. It will be further understood that the terms “includes,” “including,” “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Further, as used herein, the term “if” may be construed to mean “when” or “upon” or “in response to determining” or “in response to detecting,” depending on the context.

The disclosed embodiments provide a spin-electronics device that is using the spin of its carriers for receiving or transmitting information, and also for storing information. It should be understood that this description is not intended to limit the invention. On the contrary, the embodiments are intended to cover alternatives, modifications and equivalents, which are included in the spirit and scope of the invention as defined by the appended claims. Further, in the detailed description of the embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

### REFERENCES

The entire content of all the publications listed herein is incorporated by reference in this patent application.
[1] Safarov, V. I. et al., Recombination Time Mismatch and Spin Dependent Photocurrent at a Ferromagnetic-Metal—Semiconductor Tunnel Junction, 2022, Phys. Rev. Lett. 128, 057701, 2022, DOI: 10.1103/PhysRevLett. 128.057701.
[2] Razzoli, E. et al., Selective Probing of Hidden Spin-Polarized States in Inversion-Symmetric Bulk MoS2, Phys. Rev. Lett. 118, 086402, 2017.
[3] Kim, Y. H., Chiral-Induced spin selectivity enables a room-temperature spin light-emitting diode, Science, vol. 371, 6534, 2021, DOI: 10.1126/science.abf5291.
[4] Zhu, R., et al., Non-volatile optoelectronic memory based on a photosensitive dielectric. Nat Commun 14, 5396 (2023). doi.org/10.1038/s41467-023-40938-y

What is claimed is:

1. A spin-electronics transceiver for ultraviolet (UV) communications, the transceiver comprising:
a Si-based substrate;
an n-type semiconductor layer located on the Si-based substrate, wherein the n-type semiconductor layer includes an Sn-doped β-Ga₂O₃ material;
a p-type semiconductor layer located on the n-type semiconductor layer to form a p-n junction, the p-type semiconductor layer including MnO quantum dots, QDs; and
first and second electrodes electrically connected to the n-type semiconductor layer and the p-type semiconductor layer, respectively,
wherein spins of charge carriers in the p-type semiconductor layer are aligned according to a first direction when incident UV light has a first polarization, and according to a second direction, opposite to the first direction, when the incident UV light has a second polarization, different from the first polarization, and
wherein the first direction is associated with ones and the second direction is associated with zeros of digital data.

2. The transceiver of claim 1, wherein the Sn-doped β-Ga₂O₃ material is shaped as microflakes.

3. The transceiver of claim 2, wherein the microflakes include a single microflake.

4. The transceiver of claim 2, wherein the entire n-type semiconductor layer is made of microflakes.

5. The transceiver of claim 1, wherein the p-n junction is configured to respond only to wavelengths less than 280 nm.

6. The transceiver of claim 1, wherein the p-type semiconductor layer is in direct contact with the n-type semiconductor layer.

7. The transceiver of claim 1, further comprising:
an active layer located between the p-type semiconductor layer and the n-type semiconductor layer, wherein the p-type semiconductor layer acts as a transport layer.

8. The transceiver of claim 1, wherein the first polarization is left-hand, circular polarization and the second polarization is right-hand, circular polarization.

9. A spin-optoelectronics storage device comprising:
a Si-based substrate;
an n-type semiconductor layer located on the Si-based substrate, wherein the n-type semiconductor layer includes an Sn-doped β-Ga₂O₃ material;
a p-type semiconductor layer located on the n-type semiconductor layer to form a p-n junction, the p-type semiconductor layer including MnO quantum dots, QDs; and
first and second electrodes electrically connected to the n-type semiconductor layer and the p-type semiconductor layer, respectively,
wherein spins of charge carriers in the p-type semiconductor layer are aligned according to a first direction when incident light has a first polarization, and according to a second direction, opposite to the first direction, when the incident light has a second polarization, different from the first polarization, and
wherein the charge carriers are stored in the p-type semiconductor layer, charge carriers with spins aligned along the first direction correspond to ones of digital data, and charge carriers with spins aligned along the second direction correspond to zeros of the digital data.

10. The spin-optoelectronics storage device of claim 9, wherein the Sn-doped β-Ga₂O₃ material is shaped as microflakes.

11. The spin-optoelectronics storage device of claim 10, wherein the Sn-doped β-Ga₂O₃ material is shaped as a single microflake.

12. The spin-optoelectronics storage device of claim 10, wherein the entire n-type semiconductor layer is made of microflakes.

13. The spin-optoelectronics storage device of claim 9, wherein the p-n junction is configured to respond only to wavelengths less than 280 nm.

14. The spin-optoelectronics storage device of claim 9, wherein the p-type semiconductor layer is in direct contact with the n-type semiconductor layer.

15. The spin-optoelectronics storage device of claim 9, further comprising:
a spin filter layer configured to block carriers having a selected spin.

16. A solar-blind, visible-blind, photodetector for ultraviolet (UV) light, the photodetector comprising:
a Si-based substrate;
an n-type semiconductor layer located on the Si-based substrate, wherein the n-type semiconductor layer includes an Sn-doped β-Ga₂O₃ material;
a p-type semiconductor layer located on the n-type semiconductor layer to form a p-n junction, the p-type semiconductor layer including MnO quantum dots, QDs; and
first and second electrodes electrically connected to the n-type semiconductor layer and the p-type semiconductor layer, respectively,
wherein the p-n junction transforms the UV light into an electrical current.

17. The photodetector of claim 16, wherein the Sn-doped β-Ga₂O₃ material is shaped as microflakes.

18. The photodetector of claim 16, wherein the p-n junction is configured to respond only to wavelengths less than 280 nm.

19. The photodetector of claim 16, wherein the p-type semiconductor layer is in direct contact with the n-type semiconductor layer.

20. The photodetector of claim 16, further comprising:
an active layer located between the p-type semiconductor layer and the n-type semiconductor layer, wherein the p-type semiconductor layer acts as a transport layer.
